(19) United States
(12) Patent Application Publication
(10) Pub. No.: US 2026/0068675 A1
(43) Pub. Date: Mar. 5, 2026

(54) VAPOR CHAMBER STRUCTURE

(71) Applicant: ASIA VITAL COMPONENTS (CHINA) CO., LTD., Shenzhen (CN)

(72) Inventors: Han-Min Liu, Shenzhen (CN); Xiao-Xiang Zhou, Shenzhen (CN); Zhiwei Li, Shenzhen (CN)

(21) Appl. No.: 18/894,616

(22) Filed: Sep. 24, 2024

(30) Foreign Application Priority Data
Sep. 2, 2024 (TW) 113133126

(51) Int. Cl. H01L 23/427

(52) U.S. Cl. CPC H01L 23/427

(57) ABSTRACT

A vapor chamber structure includes an upper cover plate, a lower cover plate, at least one wick structure, and at least one carbon unit. The upper and the lower cover plate are correspondingly closed to together define a vacuum chamber between them. The vacuum chamber has a working fluid filled therein, and the wick structure is provided on an inner side surface of the lower cover plate. The carbon unit can be provided between the wick structure and the lower cover plate or on an outer side surface of the lower cover plate. Therefore, the vapor chamber structure with the carbon unit has improved ability to dissipate heat evenly and is able to achieve higher heat conduction efficiency and working fluid circulation efficiency.

This application claims the priority benefit of Taiwan patent application number 113133126 filed on Sep. 2, 2024, the disclosure of which is hereby incorporated by reference in its entirety.

### FIELD OF THE INVENTION

The present invention relates to a heat dissipation structure, and more particularly, to a vapor chamber structure.

### BACKGROUND OF THE INVENTION

The constant development of chip producing and fabricating techniques contributes to the advancement in the fields of computer and scientific computing. However, the upgraded chip performance also produces largely increased heat during the operation of chip to result in high temperature and the forming of hot spots at local areas of the chip. The heat would largely affect the chip performance and service life if it is not effectively removed from the chip.

Vapor chamber is one of many existing heat dissipation techniques applicable to electronic elements, such as chips. The vapor chamber is internally filled with a working fluid, which circulates through the vapor chamber to transfer and diffuse heat to achieve required heat dissipation and accordingly, uniform temperature of the electronic element. The existing vapor chamber structure includes an upper cover, a lower cover, and a wick structure all made of the same material, such as using copper or aluminum alone. In some vapor chamber structures, the working fluid changes in phase between vapor and liquid during its circulation in the vapor chambers. These vapor chamber structures are referred to as two-phase flow vapor chambers, which utilize phase transition to improve the achieved heat dissipation ability and temperature uniformity. However, the material properties of the vapor chamber disadvantageously prevent the vapor chamber from having further upgraded ability to achieve temperature uniformity.

In the existing chip fabrication, it has been tried to improve the chip heat dissipation by directly grows different materials on a wafer, for example, materials with good heat conduction coefficient. However, the growth of different materials on the wafer, such as a GaN on SiC wafer, would have the problem of thermal stress. That is, when the chip in operation generates high temperature, stress would cumulate at interfaces of materials having different thermal expansion coefficients to finally result in bending or even breaking of the chip. The use of different materials to fabricate chip not only increases the difficulty in chip fabrication, but also has the problem of reduced chip reliability due to thermal stress.

A prior art discloses a vapor chamber structure including a laminate of a material with good thermal conduction coefficient such as diamond and a wick structure 111. Please refer to FIG. 1. The conventional vapor chamber structure includes a lower cover plate 12 (i.e. an evaporation zone) in contact with an electronic element to absorb the heat produced by the electronic element and transfer the heat to a vacuum chamber 13 defined between the lower cover plate 12 and an upper cover plate 11. The wick structure 111 is provided on an inner wall surface of the vacuum chamber 13 in advance, and a thin film of diamond structure 112 is then provided on an inner side of the wick structure 111. A working fluid filled in the vacuum chamber 13 is in contact with the thin film of diamond structure 112 and is evaporated. When the working fluid is condensed, it flows back to a bottom of the vacuum chamber 13 along the wick structure 111 that is located at two lateral sides of the vacuum chamber 13 and spread below the thin film of diamond structure 112. According to the above conventional vapor chamber structure, heat is absorbed at the evaporation zone of the lower cover plate 12 and transferred sequentially to the wick structure 111 and the thin film of diamond structure 112 in the vacuum chamber 13. However, since the wick structure 111 has heat conduction efficiency far below that of the thin film of diamond structure 112, the heat transfer efficiency is poor and prevents the vapor chamber structure from quickly absorbing heat to enable phase transition of the working fluid to achieve the desired heat dissipation and temperature uniformity. This not only has an adverse influence on the heat conduction efficiency of the working fluid, but also results in limited circulation efficiency of the condensed working fluid. Therefore, it is necessary to improve the temperature uniformity that can be achieved by the conventional vapor chamber structure.

It is therefore tried by the inventor to provide an improved vapor chamber structure to effectively solve the problems in the conventional vapor chamber.

### SUMMARY OF THE INVENTION

A primary object of the present invention is to provide a vapor chamber structure that provides improved thermal conduction and temperature uniformity ability.

To achieve the above and other objects, the vapor chamber structure according to the present invention includes an upper cover plate, a lower cover plate, at least one wick structure, and at least one carbon unit.

The upper cover plate and the lower cover plate are correspondingly closed to each other to together define a vacuum chamber between them. The vacuum chamber is internally provided with a working fluid and having at least one wick structure provided on at least an inner side surface of the lower cover plate. The carbon unit is provided between the wick structure and the lower cover plate or on an outer side surface of the lower cover plate.

With the above arrangements, the vapor chamber structure of the present invention has improved ability to dissipate heat evenly and is able to achieve higher heat conduction efficiency and working fluid circulation efficiency.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled sectional view of a conventional vapor chamber structure;

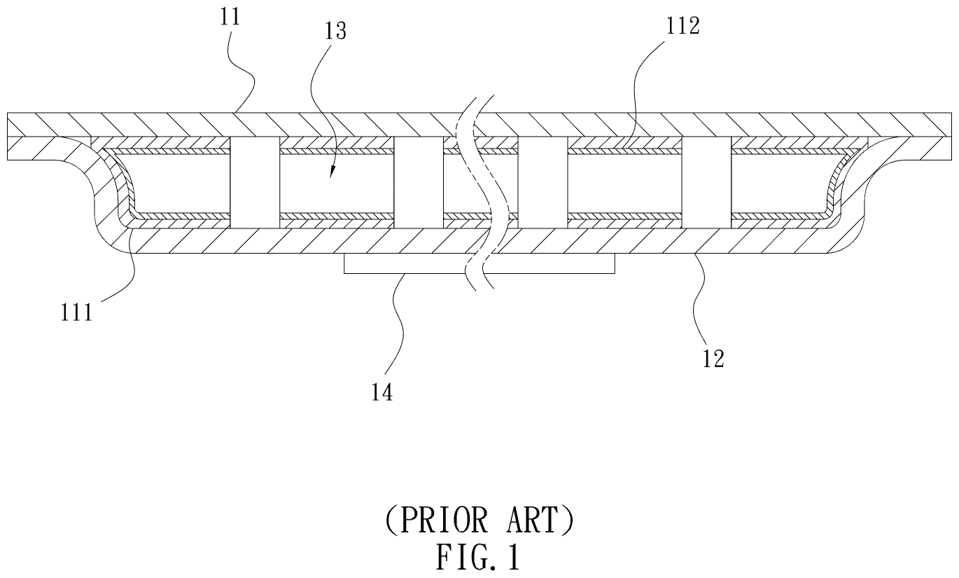

FIG. 2 is an exploded perspective view of a vapor chamber structure according to a first embodiment of the present invention;

FIG. 3 is a cutaway view of the vapor chamber structure of FIG. 2;

FIG. 4 is an assembled sectional view of the vapor chamber structure of FIG. 2;

FIG. 5 is an assembled sectional view of a vapor chamber structure according to a second embodiment of the present invention; and

FIG. 6 is an assembled sectional view of a vapor chamber structure according to a third embodiment of the present invention.

### DETAILED DESCRIPTION OF THE PREFERRED EMBODIMENTS

The present invention will now be described with some preferred embodiments thereof. For the purpose of easy to understand, elements that are the same in the preferred embodiments are denoted by the same reference numerals.

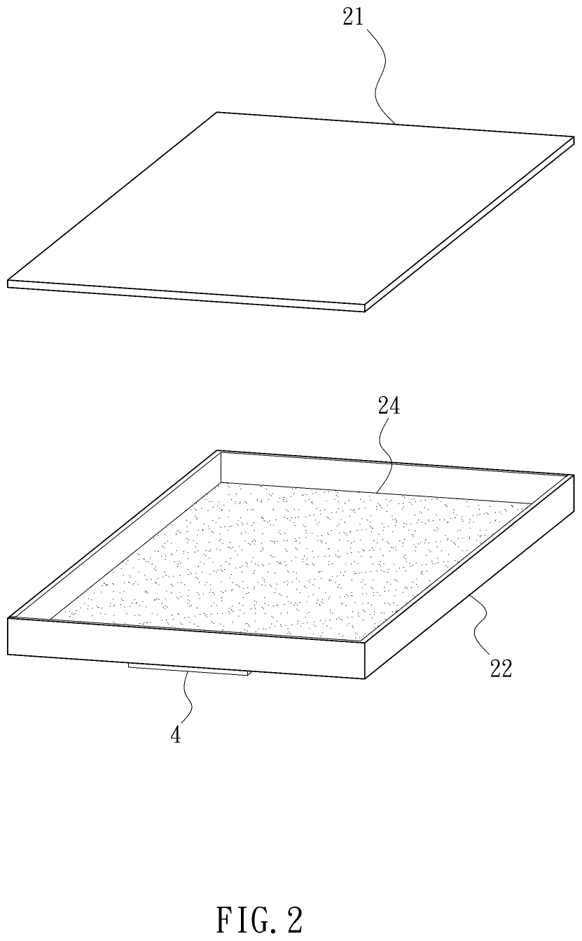

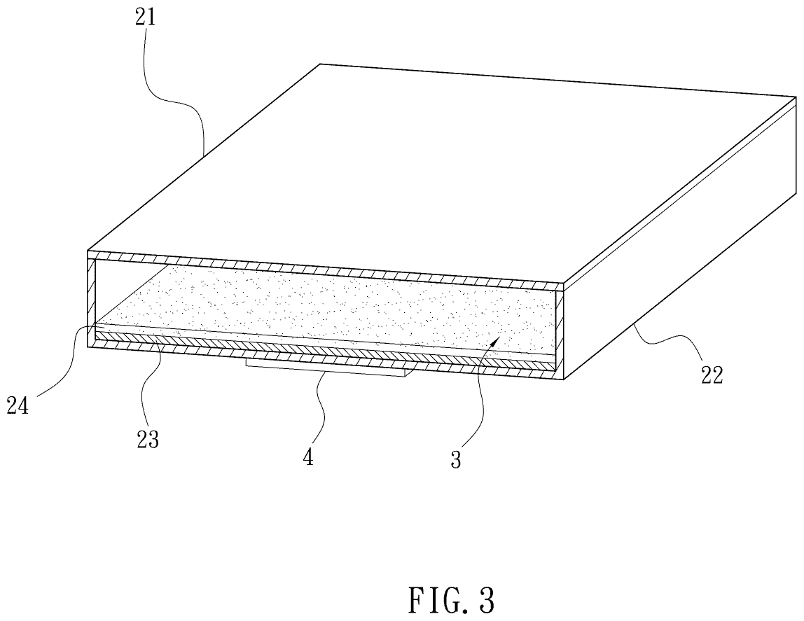

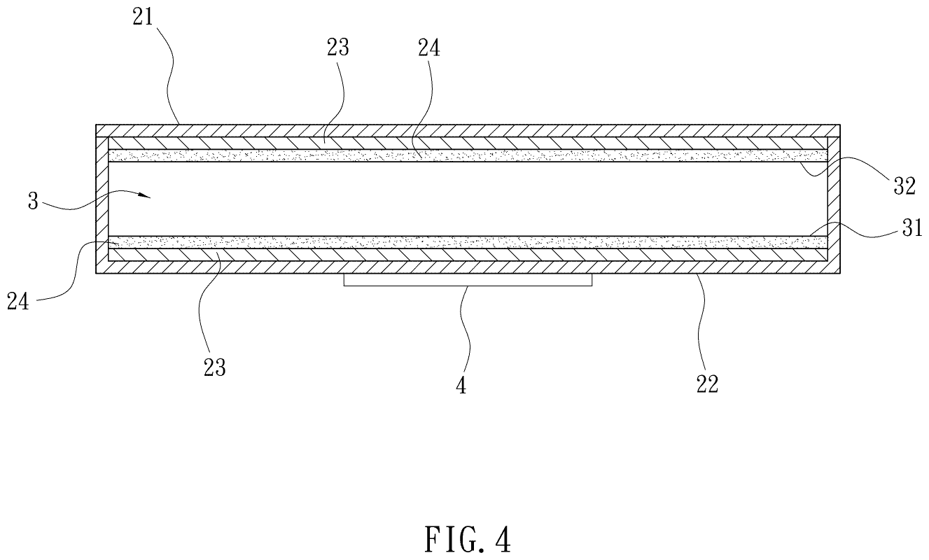

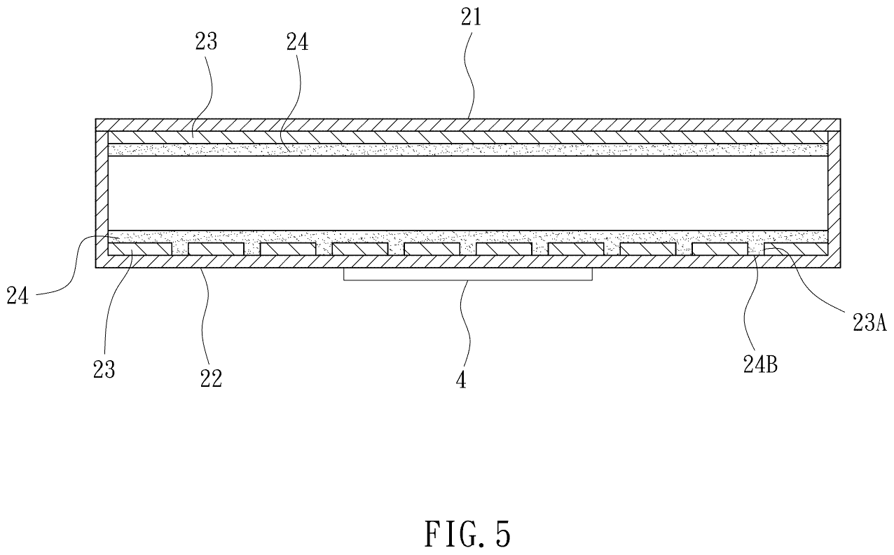

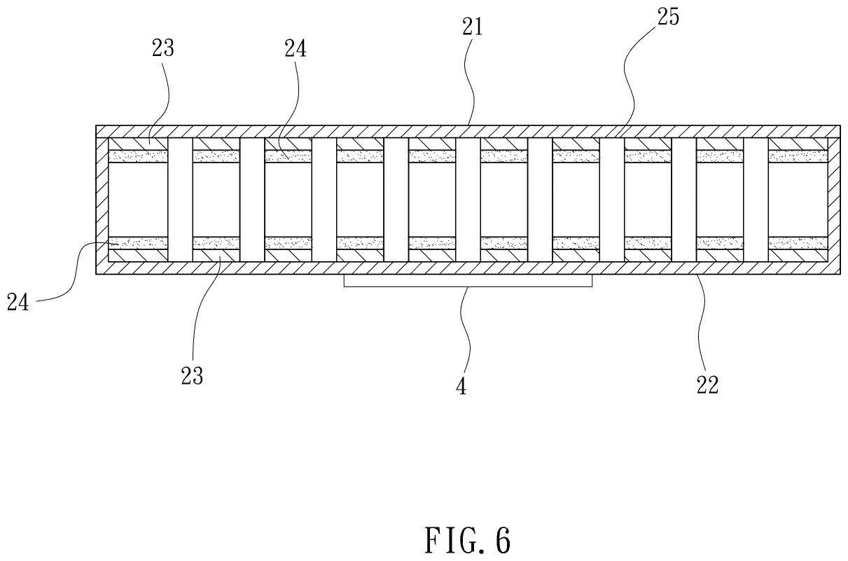

Please refer to FIGS. 2 to 6, in which FIG. 2 is an exploded perspective view of a vapor chamber structure according to a first embodiment of the present invention, FIG. 3 is a cutaway view of a first embodiment of the present invention, FIG. 4 is an assembled sectional view of the first embodiment of the present invention, FIG. 5 is an assembled sectional view of a second embodiment of the present invention, and FIG. 6 is an assembled sectional view of a third embodiment of the present invention.

As shown in FIGS. 2 and 3, the present invention provides a vapor chamber structure, a first embodiment of which includes an upper cover plate 21 and a lower cover plate 22, which are correspondingly closed to each other to define a vacuum chamber 3 between them. For example, the upper cover plate 21 and the lower cover plate 22 may respectively be a square in configuration having four sides. The four sides of the upper and the lower cover plate 21, 22 are located correspondingly to together form four vertical wall surfaces enclosing the vacuum chamber 3 therein. A joint between the closed upper and lower cover plates 21, 22 is then sealed by welded to define the vapor chamber structure.

The vacuum chamber 3 is internally filled with a working fluid (not shown). For example, the working fluid can be one of water, a coolant, methanol, acetone, liquid ammonia, and so on. That is, the vapor chamber structure is a heat dissipation solution employing the principle of gas-liquid two-phase flow, in which vapor of a liquid circulates and condensate of the vapor flows back in the vacuum chamber to achieve the effect of uniform heat spreading and dissipation.

As shown in FIG. 3, the vapor chamber structure of the present invention is further internally provided on at least an inner side surface of the lower cover plate 22 with at least one layer of wick structure 24. The wick structure 24 may be a porous or woven structure formed of a metal material, such as copper or aluminum, or a non-mental material, such as rubber or plastic, and is bonded to the inner side surface of the lower cover plate 22.

And, at least one carbon unit 23 is provided between the wick structure 24 and the lower cover plate 22 or on an outer side surface of the lower cover plate 22. The carbon unit 23 includes at least, but not limited to, amorphous carbon, carbon nanofoam, diamond, lonsdaleite, ceraphite, aggregated diamond nanorod, cyclocarbon graphene, graphite, and fullerene, all of which are allotropes of carbon. For example, when the carbon unit 23 is provided between the wick structure 24 and the lower cover plate 22, the wick structure 24 is bonded to the inner side surface of the lower cover plate 22 via the carbon unit 23. Specifically, in the present invention, the carbon unit 23 may be formed of granules containing an allotrope of carbon, which are subjected to a surface metallization process to bond to one another. Therefore, the carbon unit 23 not only has good thermal conduction the same as the allotropes of carbon (e.g. the diamond has a thermal conductivity about five times of that of copper), but also can bond stably to the metal interfaces of other components, such as the wick structure 24.

In practical use of the vapor chamber structure of the present invention, the outer side surface of the lower cover plate 22 is in contact with an electronic element 4, i.e. a heat source. As shown in FIG. 3, the vacuum chamber 3 has an evaporation side 31 corresponding to the inner side surface of the lower cover plate 22 and a condensation side 32 corresponding to an inner side surface of the upper cover plate 21. The working fluid in the vacuum chamber 3 flows through the evaporation side 31 and the condensation side 32 to repeat the evaporation and condensation process as a two-phase flow circulation to transfer and dissipate heat absorbed by the lower cover plate 22 from the electronic element 4.

That is, heat produced by the electronic element 4 is transferred from the outer side surface to the inner side surface of the lower cover plate 22. At this point, no matter the carbon unit 23 is provided between the wick structure 24 and the lower cover plate 22 or on the outer side surface of the lower cover plate 22, the heat produced by the electronic element 4 can be quickly transferred outward via the lower cover plate 22 and the carbon unit 23 without the problem of thermal resistance, so as to largely upgrade the heat conduction efficiency and heat exchange efficiency. Further, the carbon unit 23 can be in direct contact with the electronic element 4 and has the feature of high heat transfer coefficient the same as the allotropes of carbon, such as diamond, it forms a heat transfer layer at the bottom of the vapor chamber structure of the present invention to enable quick heat diffusion and highly even heat dissipation. Accordingly, the heat produced by the electronic element 4 can be quickly transferred to the wick structure 24, the porous structure of which provides a space for phase transition. The working fluid changes phases in the wick structure 24 to quickly transfer the heat from the carbon unit 23 to all directions to achieve thermal equilibrium, so as to avoid the produced heat from accumulated in the electronic element 4.

FIG. 4 shows a second embodiment of the present invention, in which two carbon units 23 are provided respectively on an inner side surface of the upper cover plate 21 and between the inner side surface of the lower cover plate 22 and the wick structure 24. In this case, the wick structure 24 can be provided on only the inner side surface of the lower cover plate 22 to bond to the lower cover plate 22 via the carbon unit 23. Alternatively, as shown in FIG. 4, two wick structures 24 are provided respectively on both the inner side surface of the upper cover plate 21 and the inner side surface of the lower cover plate 22. In this case, two carbon units 23 are provided respectively between the upper cover plate 21 and the upper wick structure 24 and between the lower cover plate 22 and the lower wick structure 24, and the two wick structures 24 are bonded to the upper cover plate 21 and the lower cover plate 22 via the carbon unit 23. It is to be noted the carbon unit 23 and the wick structure 24 located between the upper cover plate 21 and the lower cover plate 22 are not necessary in contact with each other. For example, they can be completely separated from each other at the joint between the upper cover plate 21 and the lower cover plate 22 without having any influence on the implementation of the present invention.

FIG. 5 shows a third embodiment of the present invention, in which the carbon unit 23 is provided between the wick structure 24 and the lower cover plate 22, and the carbon unit 23 is further provided with a plurality of through bores 23A, such that areas on the inner side surface of the lower cover plate 22 corresponding to the through bores 23A are exposed without the carbon unit 23 bonding thereto. Meanwhile, the wick structure 24 provided on the evaporation side 31 includes a plurality of extended portions 24B located corresponding to the through bores 23A. The extended portions 24B are downward projected from a lower side surface of the wick structure 24 to pass through and fill the through bores 23A. Thus, the extended portions 24B are directly bonded to the areas of the lower cover plate 22 that are exposed from the through bores 23A. With this arrangement, the working fluid flowing through the wick structure 24 is sucked and guided by a capillary force of the wick structure 24 to pass through the extended portions 24B into the through bores 23A to be in direct contact with the inner side surface of the lower cover plate 22. The provision of the through bores 23A not only increases the contact areas between the working fluid and the wick structure 24, but also reduces the heat exchange distance between the working fluid and the heat source, so that the vapor chamber structure of the present invention can have further improved heat conduction efficiency and ability of dissipating heat evenly.

FIG. 6 shows a third embodiment of the present invention, which further includes a plurality of spacers 25 provided in the vacuum chamber 3 to extend between the upper cover plate 21 and the lower cover plate 22. Specifically, the spacers 25 can be made of a material the same as that for forming the upper cover plate 21 and the lower cover plate 22, and are extended through the wick structure 24 and the carbon unit 23 with their two ends being directly connected to or being integrally formed with the inner side surfaces of the upper cover plate 21 and the lower cover plate 22. Therefore, the spacers 25 provide the vapor chamber structure with additional structural strength and directly guide the condensed working fluid to flow back faster. In addition, the spacers 25 may also be provided with spacer wick structure (not shown) for guiding the working fluid to flow back. It is understood, however, the present invention is not particularly limited to the above structure.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A vapor chamber structure, comprising:
an upper cover plate; and
a lower cover plate for correspondingly closed to the upper cover plate to together define a vacuum chamber between them; and the vacuum chamber being internally provided with a working fluid and having at least one wick structure provided on at least an inner side surface of the lower cover plate; and
at least one carbon unit being provided at least between the wick structure and the lower cover plate.

2. The vapor chamber structure as claimed in claim 1, wherein the vacuum chamber has an evaporation side located corresponding to the inner side surface of the lower cover plate and a condensation side located corresponding to an inner side surface of the upper cover plate.

3. The vapor chamber structure as claimed in claim 2, wherein the carbon unit is provided between the wick structure and the lower cover plate; the carbon unit having a plurality of through bores formed thereon and the wick structure including a plurality of extended portions located corresponding to the through bores on the carbon unit; and the extended portions being extended through the through bores to be directly bonded to the inner side surface of the lower cover plate.

4. The vapor chamber structure as claimed in claim 1, wherein the carbon units are provided respectively on an inner side surface of the upper cover plate and between the inner side surface of the lower cover plate and the wick structure.

5. The vapor chamber structure as claimed in claim 4, wherein the wick structures are provided respectively on the inner side surface of the upper cover plate and the inner side surface of the lower cover plate; and the carbon units are provided respectively between the upper cover plate and the wick structure and between the lower cover plate and the wick structure.

6. The vapor chamber structure as claimed in claim 2, wherein the lower cover plate has an outer side surface being in contact with an electronic element.

7. The vapor chamber structure as claimed in claim 1, further comprising a plurality of spacers provided in the vacuum chamber; and the spacers having their two ends abutted on the upper cover plate and the lower cover plate.

8. The vapor chamber structure as claimed in claim 1, wherein the carbon unit is an allotrope of carbon selected from the group consisting of amorphous carbon, carbon nanofoam, diamond, lonsdaleite, ceraphite, aggregated diamond nanorod, cyclocarbon graphene, graphite, and fullerene.
